(19) United States
(12) Patent Application Publication
(10) Pub. No.: US 2018/0331162 A1
(43) Pub. Date: Nov. 15, 2018

(54) PIXEL ELEMENT, METHOD FOR DRIVING THE SAME, DISPLAY PANEL, AND DISPLAY DEVICE

(71) Applicant: BOE Technology Group Co., Ltd., Beijing (CN)

(72) Inventors: Chang Yen WU, Beijing (CN); Chinlung LIAO, Beijing (CN); Guang YAN, Beijing (CN); Qing DAI, Beijing (CN)

(21) Appl. No.: 15/844,182

(22) Filed: Dec. 15, 2017

(30) Foreign Application Priority Data
May 11, 2017 (CN) 201710331392.3

(51) Int. Cl. H01L 27/32; H01L 51/52

(52) U.S. Cl. CPC H01L 27/3211; G09G 2300/0452; H01L 51/5234; H01L 51/5206

(57) ABSTRACT

The disclosure relates to a pixel element, a method for driving the same, a display panel, and a display device. The pixel element includes at least two sub-pixels, each of which includes a first electrode, a first light emitting layer, a second electrode, a second light emitting layer, and a third electrode arranged in that order, wherein there is at least one sub-pixel which includes a first light emitting layer and a second light emitting layer with different emission colors; and a total number of emission colors of all light emitting layers in the at least two sub-pixels is at least three.

### CROSS-REFERENCE TO RELATED APPLICATION

This Application claims priority to Chinese Patent Application No. 201710331392.3, filed on May 11, 2017, the content of which is incorporated by reference in the entirety.

### TECHNICAL FIELD

The present disclosure relates to the field of display technologies, and particularly to a pixel element, a method for driving the same, a display panel, and a display device.

### DESCRIPTION OF THE RELATED ART

At present, an Organic Light Emitting Diode (OLED) display product has been accepted as a next generation of display technology due to its self-illuminating, high response speed, wide angle of view, high brightness, high chroma, light weight, and other advantages. Each pixel element in the existing OLED display panel includes at least three sub-pixels, each of which includes an OLED light emitting device, and the existing OLED light emitting device generally includes an anode, an organic light emitting layer, and a cathode. Typically each OLED light emitting device can only emit light in one color, so in order to make the OLED display product to display in full color, each pixel element shall include sub-pixels in at least three different colors, and if a wide color gamut is required, then sub-pixels in a larger number of colors will be desirable, but if there are a larger number of sub-pixels in each pixel element, then it will be more difficult to accommodate a high Pixels-Per-Inch (PPI), and a wide color gamut as required for the display panel.

In summary, it is highly desirable at present to address the problem of how to accommodate a high PPI and a wide color gamut as required for the OLED display panel.

### SUMMARY

In one aspect, an embodiment of the disclosure provides a pixel element including at least two sub-pixels, each sub-pixel includes a first electrode, a first light emitting layer, a second electrode, a second light emitting layer, and a third electrode arranged sequentially, wherein: there is at least one sub-pixel which includes a first light emitting layer and a second light emitting layer with different emission colors; and a total number of emission colors of all light emitting layers in the at least two sub-pixels is at least three.

In one or more embodiments, the first electrode in the each sub-pixel is an anode, the third electrode in the each sub-pixel is a cathode; and the second electrode in the each sub-pixel is a cathode relative to the first electrode in the each sub-pixel, and an anode relative to the third electrode in the each sub-pixel.

In one or more embodiments, orthographic projections of the first light emitting layer and the second light emitting layer in the each sub-pixel onto the second electrode in the each sub-pixel overlap with each other.

In one or more embodiments, the second electrode in the each sub-pixel is structured in a layer, or a stack of layers.

In one or more embodiments, a total thickness of the second electrode in the each sub-pixel is less than 20 nanometers.

In one or more embodiments, the second electrode in the each sub-pixel is a transparent electrode.

In one or more embodiments, the each sub-pixel of the pixel element is a sub-pixel which includes a first light emitting layer and a second light emitting layer with different emission colors.

In one or more embodiments, there are different emission colors of respective light emitting layers in the pixel element.

In one or more embodiments, the pixel element includes three sub-pixels, and a total number of emission colors of all light emitting layers in the three sub-pixels is at least four.

In another aspect, an embodiment of the disclosure further provides a display panel including a pixel element, the pixel element includes at least two sub-pixels, each sub-pixel includes a first electrode, a first light emitting layer, a second electrode, a second light emitting layer, and a third electrode arranged sequentially, wherein: there is at least one sub-pixel which includes a first light emitting layer and a second light emitting layer with different emission colors; and a total number of emission colors of all light emitting layers in the at least two sub-pixels is at least three.

In one or more embodiments, orthographic projections of the first light emitting layer and the second light emitting layer in the each sub-pixel onto the second electrode in the each sub-pixel overlap with each other.

In one or more embodiments, the each sub-pixel of the pixel element is a sub-pixel which includes a first light emitting layer and a second light emitting layer with different emission colors.

In one or more embodiments, there are different emission colors of respective light emitting layers in the pixel element.

In one or more embodiments, the pixel element includes three sub-pixels, and a total number of emission colors of all light emitting layers in the three sub-pixels is at least four.

In still another aspect, an embodiment of the disclosure further provides a display device, including the display panel according to the embodiment of the disclosure.

In still another aspect, an embodiment of the disclosure further provides a method for driving the pixel element above according to the embodiment of the disclosure, including: applying a first signal to the first electrode and the third electrode in the each sub-pixel of the pixel element, and a second signal to the second electrode in the each sub-pixel of the pixel element through a drive power supply; and adjusting a difference in potential between the second signal and the first signal to control the first light emitting layer and the second light emitting layer in the each sub-pixel of the pixel element to emit light in a time division mode.

In one or more embodiments, adjusting the difference in potential between the second signal and the first signal to control the first light emitting layer and the second light emitting layer in the each sub-pixel of the pixel element to emit light in the time division mode includes: adjusting the difference in potential between the second signal and the first signal to a negative value, so that the first light emitting layer in the each sub-pixel of the pixel element emits light, and the second light emitting layer in the each sub-pixel of the pixel element does not emit light; and adjusting the difference in potential between the second signal and the first signal to a positive value, so that the first light emitting layer in the each sub-pixel of the pixel element does not emit light, and the second light emitting layer in the each sub-pixel of the pixel element emits light.

In one or more embodiments, amplitude of the difference in potential is positively correlated with strengths of light emitted from the first light emitting layer and the second light emitting layer in the each sub-pixel of the pixel element.

In one or more embodiments, the difference in potential is maintained for a length of time positively correlated with lengths of time for which the first light emitting layer and the second light emitting layer in the each sub-pixel of the pixel element emit light.

In one or more embodiments, the drive power supply includes a pulse power supply, an alternating-current power supply, or an alternating-current power supply plus a direct-current power supply.

### BRIEF DESCRIPTION OF THE DRAWINGS

In order to make the technical solutions according to the embodiments of the present disclosure more apparent, the drawings to which a description of the embodiments refers will be briefly introduced below, and apparently the drawings to be described below are merely illustrative of some of the embodiments of the present disclosure, and those ordinarily skilled in the art can derive from these drawings other drawings without any inventive effort.

FIG. 1 is a schematic structural diagram of a pixel element including two sub-pixels according to an embodiment of the disclosure;

FIG. 2 is a schematic structural diagram of a sub-pixel according to an embodiment of the disclosure;

FIG. 3 is a schematic structural diagram of a pixel element including three sub-pixels according to an embodiment of the disclosure;

FIG. 4 is a schematic flow chart of a method for driving a pixel element according to an embodiment of the disclosure;

FIG. 5 is a schematic structural diagram of a drive circuit of a sub-pixel according to an embodiment of the disclosure.

### DETAILED DESCRIPTION OF THE EMBODIMENTS

The technical solutions according to the embodiments of the disclosure will be described below clearly and fully with reference to the drawings in the embodiments of the disclosure, and apparently the embodiments described here are only a part but not all of the embodiments of the disclosure. Based upon the embodiments here of the disclosure, all the other embodiments which can occur to those ordinarily skilled in the art without any inventive effort shall fall into the scope of the disclosure as claimed.

The shapes and sizes of respective components in the drawings are not intended to reflect any real proportion, but merely intended to illustrate the content of the disclosure.

A pixel element according to an embodiment of the disclosure is provided as a result of redesigning and optimizing the structure of a sub-pixel in the existing pixel element by arranging two light emitting layers with different emission colors in at least one sub-pixel. The disclosure will be applicable to any type of OLED display panel. A particular structure thereof will be described below in details.

As illustrated in FIG. 1 which is a schematic structural diagram of a pixel element according to an embodiment of the disclosure, the pixel element 1 includes at least two sub-pixels 10 and 11. In order to display in full color, typically sub-pixels in at least three different colors need to be arranged in each pixel element in the related art, but only two sub-pixels need to be arranged to display in full color in the disclosure.

In order to display in full color, a light emitting layer and an electrode need to be added to a sub-pixel, and since respective sub-pixels in the pixel element are structurally similar to each other except the emission colors of the first light emitting layer and the second light emitting layer arranged in each sub-pixel can be set as needed, only the sub-pixel 10 will be described below in details by way of an example.

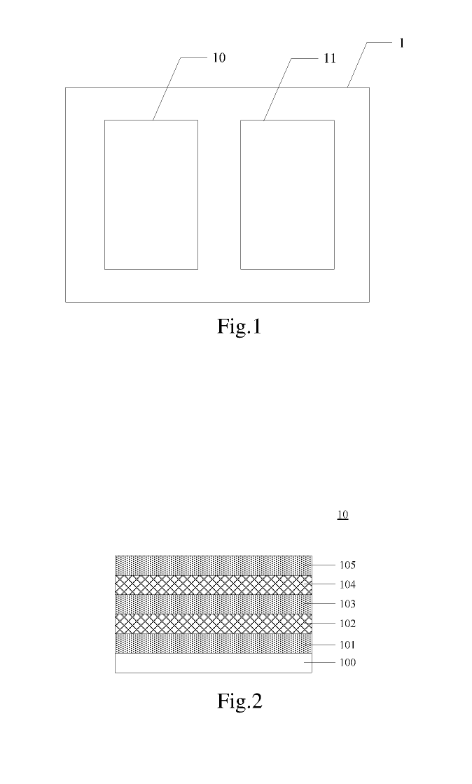

In some embodiments, as illustrated in FIG. 2, each sub-pixel in the pixel element includes a first electrode 101, a first light emitting layer 102, a second electrode 103, a second light emitting layer 104, and a third electrode 105 arranged in that order, where there is at least one sub-pixel which includes a first light emitting layer and a second light emitting layer with different emission colors; and the total number of emission colors of all the light emitting layers in the at least two sub-pixels of the pixel element is at least three (i.e. greater than or equal to three), or in other words, all the light emitting layers in the at least two sub-pixels of the pixel element at least have three different emission colors.

That is, each sub-pixel according to the embodiment of the disclosure includes a first light emitting layer and a second light emitting layer arranged in a stack, and the same or different colors of light emitted from these two light emitting layers may be set as needed, for example, the first light emitting layer emits yellow light, and the second light emitting layer emits red light, or both the first light emitting layer and the second light emitting layer emit red light. Thus when there are different emission colors of the two light emitting layers, the sub-pixel can be enabled to emit light rays in a larger number of colors, thus improving the color gamut of the display panel.

Since each pixel element includes at least two sub-pixels, and at least one sub-pixel in the each pixel element is a sub-pixel which includes a first light emitting layer and a second light emitting layer with different emission colors, all the light emitting layers in the each pixel element can emit light in at least two different colors. Further, in order to display in full color, the total number of emission colors of all the light emitting layers in the at least two sub-pixels of the each pixel element is greater than or equal to three, i.e. all the light emitting layers in the each pixel element should emit light in at least three different colors, for example, all the light emitting layers in the each pixel element can be arranged to emit light in four different colors as needed to thereby further improve the color gamut of the pixel element so as to accommodate a wide color gamut as required for the display panel.

In a particular implementation, only two sub-pixels can be arranged in each pixel element to display in full color, thus reducing the number of sub-pixels in the pixel element so as to make it easier to accommodate a high PPI as required for the display panel. For example, there are a smaller number of sub-pixels in each pixel element according to the embodiment of the disclosure in a display panel with a certain area (e.g., a 5-inch display panel of a mobile phone), so the size of each pixel element and each sub-pixel can be made larger while being fabricated. In other words, with the pixel element according to the embodiment of the disclosure, a larger number of pixel elements can be fabricated in the display panel with the same area via the same process capability to thereby accommodate a high PPI as required for the display panel.

In order to drive the two light emitting layers respectively to emit light, electrodes need to be arranged on both sides of each light emitting layer, but in fact, the terms “first”, “second”, “third”, etc., are only intended to distinguish the light emitting layers or the electrodes from each other, but not to limit the disclosure thereto.

In some embodiments, the outmost two electrodes are an anode and a cathode respectively, and the middle electrode may act as either an anode or a cathode dependent upon a real structural design of the sub-pixel. As illustrated in FIG. 2, the first electrode 101, the first light emitting layer 102, the second electrode 103, the second light emitting layer 104, and the third electrode 105 are arranged on a base substrate 100 in that order, and the first electrode 101 is an anode, the third electrode 105 is a cathode, and the second electrode 103 is a cathode relative to the first electrode 101, and an anode relative to the third electrode 105.

In some embodiments, in order to enable uniform light rays to be emitted from the first light emitting layer and the second light emitting layer in a sub-pixel, the two light emitting layers in the sub-pixel are arranged in the same size. In some embodiments, orthographic projections of the first light emitting layer and the second light emitting layer in each sub-pixel onto the second electrode in the each sub-pixel overlap with each other.

In some embodiments, the second electrode arranged between the two light emitting layers is structured in a layer, or a stack of layers; and it shall be noted that, the particular structure of the second electrode will not be limited to the structure above, but can alternatively be set as another structure as needed.

In some embodiments, take the structure illustrated in FIG. 2 as a top-emitting structure for example, in order to enable light rays emitted from the first light emitting layer to pass and exit the second electrode, the total thickness of the second electrode is less than 20 nanometers, and the second electrode is a transparent electrode.

In some embodiments, the material of the second electrode is one or a combination of conductive oxide, metal, metal oxide, and an organic material; and it shall be noted that, the material of the second electrode can also be selected as needed as long as it is transparent, and can act as both an anode and a cathode.

In some embodiments, each sub-pixel in a pixel element is a sub-pixel which includes a first light emitting layer and a second light emitting layer with different emission colors. Take the pixel element which includes two sub-pixels 10 and 11 illustrated in FIG. 1 as an example, in this case, the emission color of the first light emitting layer in the sub-pixel 10 is different from that of the second light emitting layer in the sub-pixel 10; and the emission color of the first light emitting layer in the sub-pixel 11 is different from that of the second light emitting layer in the sub-pixel 11.

In some embodiments, in order to further improve the color gamut and increase the number of colors of light which can be emitted from a pixel element, there are different emission colors of respective light emitting layers in the pixel element, i.e. the emission colors of respective light emitting layers in the pixel element are different from one another. Still take the pixel element which includes two sub-pixels 10 and 11 illustrated in FIG. 1 as an example, in this case, respective emission colors of the four light emitting layers in the two sub-pixels are different from one another, that is, there are light emitting layers in four different emission colors in the two sub-pixels.

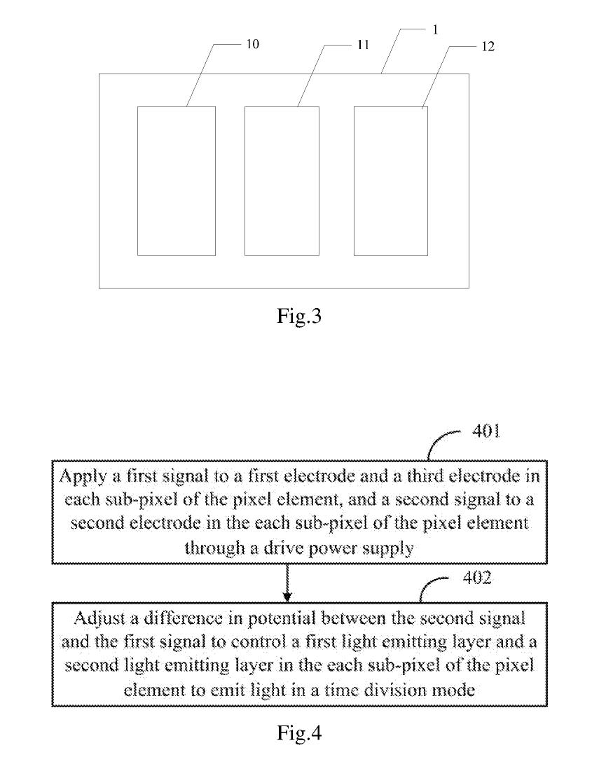

In a particular implementation, the pixel element according to the embodiment of the disclosure can include more than two sub-pixels instead of two sub-pixels, for example, each pixel element includes three sub-pixels. As compared with the related art in which the pixel element includes sub-pixels in three colors, each pixel element according to the embodiment of the disclosure can include light emitting layers in at least four different emission colors, and as illustrated in FIG. 3 which is a schematic structural diagram of a pixel element including three sub-pixels according to an embedment of the disclosure, the pixel element includes three sub-pixels, and the total number of emission colors of all the light emitting layers in the three sub-pixels is at least four, that is, there are light emitting layers in at least four different emission colors in the sub-pixel 10, the sub-pixel 11, and the sub-pixel 12.

In some embodiments, the pixel element includes three sub-pixels, and there are two light emitting layers in each sub-pixel, where the emission color of each light emitting layer can be set as needed in reality. For example, the emission colors of respective light emitting layers in the three sub-pixels can be set as different from one another (in this case, the total number of emission colors of all the light emitting layers in the three sub-pixels is six), or the emission color of the first light emitting layer in each sub-pixel of the three sub-pixel may be set as blue, and the emission colors of the respective second light emitting layers in the three sub-pixels may be set as red, green, and yellow respectively (in this case, the total number of emission colors of all the light emitting layers in the three sub-pixels is four).

Based upon the same inventive concept, an embodiment of the disclosure further provides a display panel including the pixel element above according to any one of the embodiments of the disclosure. Reference can be made to any one of the embodiments of the pixel element above for an implementation of the display panel, thus a repeated description thereof will be omitted here.

Based upon the same inventive concept, an embodiment of the disclosure further provides a display device including the display panel above according to the embodiment of the disclosure. Reference can be made to the embodiment of the display panel above for an implementation of the display device, thus a repeated description thereof will be omitted here.

Based upon the same inventive concept, an embodiment of the disclosure further provides a method for driving a pixel element, as illustrated in FIG. 4, which can includes the following operations.

The operation 401 is to apply a first signal to a first electrode and a third electrode in each sub-pixel of the pixel element, and a second signal to a second electrode in the each sub-pixel of the pixel element through a drive power supply.

The operation 402 is to adjust a difference in potential between the second signal and the first signal to control a first light emitting layer and a second light emitting layer in the each sub-pixel of the pixel element to emit light in a time division mode.

In a particular implementation, each sub-pixel in the pixel element according to the embodiment of the disclosure includes a first electrode, a first light emitting layer, a second electrode, a second light emitting layer, and a third electrode arranged sequentially, and while the first light emitting layer and the second light emitting layer are emitting light, actually the difference in potential will be formed between the two electrodes on both sides of each of the light emitting layers, and the magnitude and the negative or positive sign of the difference in potential can be adjusted to thereby control the light emitting layer to emit light.

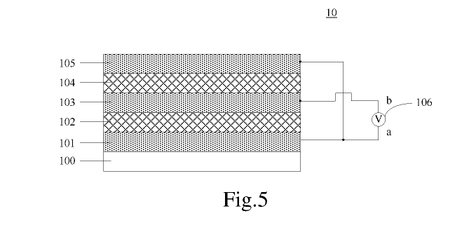

The first signal is applied to the first electrode and the third electrode in each of the sub-pixels in the pixel element, and the second signal is applied to the corresponding second electrode through the driver power source In the operation 401; and as illustrated in FIG. 5 which is a schematic structural diagram of a drive circuit of a sub-pixel according to an embodiment of the disclosure, 106 represents a drive power supply configured to form the difference in potential between two electrodes on both sides of a light emitting layer, the first electrode and the third electrode are connected with the terminal a of the drive power supply 106, and have the same potential, and the drive power supply can apply the first signal to the first electrode and the third electrode from the terminal a thereof; and the second electrode is connected with the terminal b of the drive power supply 106, and the drive power supply can apply the second signal to the second electrode from the terminal b thereof, so that the drive power supply can form the differences in potential between the first electrode and the second electrode, and between the third electrode and the second electrode.

Since the first light emitting layer and the second light emitting layer are arranged vertically in a stack, and if the respective light emitting layers emit light in a time division mode in a very short period of time, then they will emit light for such a short period of time that it will be very difficult for human eyes to differentiate them, but the light emitting layers will be perceived as emitting light at the same time. Accordingly in the pixel element according to the embodiment of the disclosure, the color of light emitted from each sub-pixel can be controlled simply by controlling the periods of time for which, and the strengths at which the two light emitting layers in the sub-pixel emit light.

Generally, the brightness of a light emitting layer may be affected by the value of voltage applied to an anode above the light emitting layer, therefore, in some embodiments, the amplitude of the difference in potential is positively correlated with the strengths of light emitted from the first light emitting layer and the second light emitting layer. Also the length of time for which the light emitting layer emits light may be affected directly by the length of time for which the voltage is applied to the anode above the light emitting layer, and therefore, in some embodiments, the difference in potential is maintained for a length of time positively correlated with the lengths of time for which the first light emitting layer and the second light emitting layer emit light.

The first light emitting layer and the second light emitting layer in the each sub-pixel can be controlled to emit light in a time division mode, in the operation 402 by adjusting the difference in potential between the second signal and the first signal to a negative value, so that the first light emitting layer in the each sub-pixel emits light, and the second light emitting layer in the each sub-pixel does not emit light; and adjusting the difference in potential to a positive value, so that the first light emitting layer in the each sub-pixel does not emit light, and the second light emitting layer in the each sub-pixel emits light.

In a particular implementation, the first electrode is an anode, the third electrode is a cathode, and the second electrode is a cathode relative to the first electrode, and an anode relative to the third electrode. Also since there is the same potential of the first electrode and the third electrode, when the difference in potential between the second signal and the first signal is adjusted to a negative value, there is equivalently positive voltage applied across the anode and the cathode corresponding to the first light emitting layer, so the first light emitting layer can emit light, and there is equivalently negative voltage applied across the anode and the cathode corresponding to the second light emitting layer, so the second light emitting layer will not emit light; and when the difference in potential between the second signal and the first signal is adjusted to a positive value, there is equivalently positive voltage applied across the anode and the cathode corresponding to the second light emitting layer, so the second light emitting layer can emit light, and there is equivalently negative voltage applied across the anode and the cathode corresponding to the first light emitting layer, so the first light emitting layer will not emit light.

In some embodiments, the drive power supply above can be selected as needed in reality, but will not be limited to any particular type thereof as long as the differences in potential can be formed between the first electrode and the second electrode, and between the third electrode and the second electrode. In some embodiments, the drive power supply includes but will not be limited to a pulse power supply, an alternating-current power supply, or an alternating-current power supply plus a direct-current power supply.

In summary, the pixel element according to the embodiment of the disclosure includes at least two sub-pixels, and there is at least one sub-pixel which includes a first light emitting layer and a second light emitting layer with different emission colors, so that there may be a larger number of colors of light rays emitted from a sub-pixel, and the total number of emission colors of all the light emitting layers in each pixel element is at least three, so each pixel element can display in full color using only two sub-pixels, thus reducing the number of sub-pixels in the pixel element so as to make it easier to accommodate a high PPI and a wide color gamut as required for the display panel.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A pixel element, comprising at least two sub-pixels, each sub-pixel comprises a first electrode, a first light emitting layer, a second electrode, a second light emitting layer, and a third electrode arranged sequentially, wherein:
there is at least one sub-pixel which comprises a first light emitting layer and a second light emitting layer with different emission colors; and a total number of emission colors of all light emitting layers in the at least two sub-pixels is at least three.

2. The pixel element according to claim 1, wherein the first electrode in the each sub-pixel is an anode, the third electrode in the each sub-pixel is a cathode; and the second electrode in the each sub-pixel is a cathode relative to the first electrode in the each sub-pixel, and an anode relative to the third electrode in the each sub-pixel.

3. The pixel element according to claim 1, wherein orthographic projections of the first light emitting layer and the second light emitting layer in the each sub-pixel onto the second electrode in the each sub-pixel overlap with each other.

4. The pixel element according to claim 1, wherein the second electrode in the each sub-pixel is structured in a layer, or a stack of layers.

5. The pixel element according to claim 1, wherein a total thickness of the second electrode in the each sub-pixel is less than 20 nanometers.

6. The pixel element according to claim 1, wherein the second electrode in the each sub-pixel is a transparent electrode.

7. The pixel element according to claim 1, wherein the each sub-pixel of the pixel element is a sub-pixel which includes a first light emitting layer and a second light emitting layer with different emission colors.

8. The pixel element according to claim 7, wherein there are different emission colors of respective light emitting layers in the pixel element.

9. The pixel element according to claim 1, wherein the pixel element comprises three sub-pixels, and a total number of emission colors of all light emitting layers in the three sub-pixels is at least four.

10. A display panel, comprising a pixel element, the pixel element comprises at least two sub-pixels, each sub-pixel comprises a first electrode, a first light emitting layer, a second electrode, a second light emitting layer, and a third electrode arranged sequentially, wherein:
there is at least one sub-pixel which comprises a first light emitting layer and a second light emitting layer with different emission colors; and a total number of emission colors of all light emitting layers in the at least two sub-pixels is at least three.

11. The display panel according to claim 10, wherein orthographic projections of the first light emitting layer and the second light emitting layer in the each sub-pixel onto the second electrode in the each sub-pixel overlap with each other.

12. The display panel according to claim 10, wherein the each sub-pixel of the pixel element is a sub-pixel which includes a first light emitting layer and a second light emitting layer with different emission colors.

13. The display panel according to claim 12, wherein there are different emission colors of respective light emitting layers in the pixel element.

14. The display panel according to claim 10, wherein the pixel element comprises three sub-pixels, and a total number of emission colors of all light emitting layers in the three sub-pixels is at least four.

15. A display device, comprising the display panel according to claim 10.

16. A method for driving the pixel element according to claim 1, the method comprising:
applying a first signal to the first electrode and the third electrode in the each sub-pixel of the pixel element, and a second signal to the second electrode in the each sub-pixel of the pixel element through a drive power supply; and
adjusting a difference in potential between the second signal and the first signal to control the first light emitting layer and the second light emitting layer in the each sub-pixel of the pixel element to emit light in a time division mode.

17. The method according to claim 16, wherein adjusting the difference in potential between the second signal and the first signal to control the first light emitting layer and the second light emitting layer in the each sub-pixel of the pixel element to emit light in the time division mode comprises:
adjusting the difference in potential between the second signal and the first signal to a negative value, so that the first light emitting layer in the each sub-pixel of the pixel element emits light, and the second light emitting layer in the each sub-pixel of the pixel element does not emit light; and
adjusting the difference in potential between the second signal and the first signal to a positive value, so that the first light emitting layer in the each sub-pixel of the pixel element does not emit light, and the second light emitting layer in the each sub-pixel of the pixel element emits light.

18. The method according to claim 17, wherein amplitude of the difference in potential is positively correlated with strengths of light emitted from the first light emitting layer and the second light emitting layer in the each sub-pixel of the pixel element.

19. The method according to claim 17, wherein the difference in potential is maintained for a length of time positively correlated with lengths of time for which the first light emitting layer and the second light emitting layer in the each sub-pixel of the pixel element emit light.

20. The method according to claim 17, wherein the drive power supply comprises a pulse power supply, an alternating-current power supply, or an alternating-current power supply plus a direct-current power supply.
